(19) United States
(12) Patent Application Publication
(10) Pub. No.: US 2026/0082656 A1
(43) Pub. Date: Mar. 19, 2026

(54) SEMICONDUCTOR TRANSISTOR DEVICE AND METHOD OF MANUFACTURING THE SAME

(71) Applicant: Infineon Technologies Austria AG, Villach (AT)

(72) Inventors: Alessandro Ferrara, Villach (AT); Riccardo Tambone, Villach (AT)

(21) Appl. No.: 19/300,736

(22) Filed: Aug. 15, 2025

(30) Foreign Application Priority Data
Sep. 13, 2024 (DE) 102024126458.6

(51) Int. Cl. H10D 64/00; H10D 30/01; H10D 30/66; H10D 62/17; H10D 64/23

(52) U.S. Cl. CPC H10D 64/115; H10D 30/0291; H10D 30/668; H10D 62/393; H10D 64/117; H10D 64/2527

(57) ABSTRACT

The invention relates to a semiconductor transistor device, including: a field electrode trench in a semiconductor body; a field electrode in the field electrode trench; and a field electrode contact electrically contacting the field electrode. The field electrode trench and the field electrode have an elongated lateral extension in a length direction. A specific resistance in the semiconductor body aside the field electrode trench increases along the length direction from a first position aside the field electrode contact to a second position away from the first position.

### TECHNICAL FIELD

The present disclosure relates to a semiconductor transistor device and a method of manufacturing the same.

### BACKGROUND

The semiconductor transistor device may have a field electrode in a field electrode trench, both having an elongated lateral extension in a length direction. Such an elongated field electrode may also be referred to as a field plate, it capacitively couples to the semiconductor body, for instance to a drift region of the transistor device. Via a field electrode contact, which is electrically connected to the field electrode, a drive voltage may be applied to the field electrode, e.g. for a field shaping during a switching of the transistor device.

### SUMMARY

Examples of the present disclosure are directed at a semiconductor transistor device with a field electrode in a trench.

In an embodiment, a specific resistance R in the semiconductor body aside the field electrode trench increases along the length direction of the trench and field electrode. In detail, the specific resistance R may increase from a first position x₁ aside the field electrode contact, which electrically contacts the field electrode, to a second position x₂ away from the first position. The smaller specific resistance R close to the position x₁ allows to reduce the device resistance Ron in comparison to a traditional device with a uniform specific resistance between x₁ and x₂. When optimizing the semiconductor device to achieve the lowest Ron, the specific resistance R* at a given position x* is limited by the trade-off with the VFPmax, which is the maximum voltage on the field-plate electrode before the device loses its capability to block the drain-to-source voltage and enters dynamic avalanche. In a conventional device with a constant specific resistance laterally along the field plate, the second position x₂, where the field plate voltage is high during switching due to the distance from the field electrode contact, may limit a further Ron reduction (because Ron must be sufficiently high to avoid dynamic avalanche).

Vice versa, with the specific resistance increasing away from the field electrode contact, a smaller Ron is realized where the field electrode voltage is low due to the proximity to the field electrode contact, e.g. where the field electrode is tied to the source voltage (or to another defined field electrode voltage). Vice versa, at the second position, which lies further away from (such as distal to) the field electrode contact and where the field electrode voltage is higher during switching, the specific resistance R and, in consequence, Ron and VFPmax, are higher. In other words, the specific resistance R increasing from the field electrode contact to the second position may allow for a good dynamic avalanche performance with a reduced impact on the Ron.

Particular embodiments and features are provided throughout this disclosure and in particular in the dependent claims. Thereby, the individual features shall be disclosed independently of a specific claim category, the disclosure relates to apparatus and device aspects, but also to method and use aspects. If for instance a device manufactured or used in a specific way is described, this is also a disclosure of a respective manufacturing process or use, and vice versa. In general words, an approach of this disclosure is to provide a field electrode trench with a varying specific resistance in the semiconductor body aside, e.g. increasing specific resistance R away from the field electrode contact.

As discussed in further detail below and illustrated in the exemplary embodiments, “increase” or “increasing” may relate to a continuous or stepwise increase in the length direction, wherein combinations are possible as well (continuous increase in a section and stepwise increase in another section along the length direction). Therein, “stepwise” may relate to one single step or to a plurality of steps, e.g. a plurality of consecutive sections with a specific resistance R increasing from section to section.

In the “length direction”, which is a lateral direction, the field electrode trench and trench electrode have an elongated extension. In a transverse direction, e.g. a lateral direction perpendicular to the length direction, for instance a plurality of device cells can be arranged consecutively. As discussed in further detail below, a width of the field electrode trench and/or distance between neighboring field electrode trenches may be taken in the transverse direction. Any lateral direction, e.g. the length direction or the transverse direction, may lie perpendicular to a vertical direction, which can for instance lie perpendicular to a surface of the device, e.g. a surface of a substrate or of an epitaxial layer on the substrate.

With respect to the vertical direction, the semiconductor body may have a first side and an opposite second side, the field electrode trench extending for instance from the first side into the semiconductor body. The semiconductor body may comprise a semiconductor substrate, e.g. forming the second side of the semiconductor body. On the semiconductor substrate, an epitaxial semiconductor layer or layers may be arranged. That side of an uppermost epitaxial layer, which faces away from the semiconductor substrate, can for instance form the first side of the semiconductor body.

The semiconductor device may comprise a first load region at the first side and a second load region at the second side of the semiconductor body. In general, the semiconductor device can for instance be an IGBT, the load regions being an emitter and a collector. In an embodiment, however, the device is a FET, the load regions being a source and a drain region, for instance the source region arranged at the first side and the drain region arranged at the second side of the semiconductor body. In general, a lateral channel is conceivable, e.g. with a gate electrode arranged above the first side of the semiconductor body. In an embodiment, however, the device may comprise a gate electrode in a trench. In this case, a body region may be arranged laterally aside the trench with the gate electrode, e.g. vertically between the source and drain region. Independently of these details, a current flow through the device may be vertical (e.g. apart from a certain lateral component due to a current spreading), for instance at least in the drift region and/or aside the field electrode trench. In other words, the specific resistance R at a respective position (e.g. x₁, x₂, see above) may be taken in the vertical direction, i.e. be a vertical resistance.

In general, separate trenches may be provided for the gate and the field electrode, e.g. arranged consecutive in the transverse direction. Alternatively, and as illustrated in the exemplary embodiments, the gate electrode may be arranged above the field electrode in the same field electrode trench. Independently of these details, the field electrode trench may extend into a drift region of the device, which may be made of the same doping type but with a lower doping concentration compared to the second load region, for instance drain region. Generally, the first and second load region may be made of a first doping type, e.g. in combination with a body region made of a second doping type. In embodiments of this application, the first type is n-type and the second type is p-type.

At the second position, towards which the specific resistance R increases from the first position, for instance no contact to the field electrode may be arranged. In other words, the second position may be considered as an “open end”, which can either be an actual end of the field electrode or a central position between the field electrode contact and another field electrode contact. Independently of whether the open end is the actual end or the center point between two field electrode contacts, the field plate voltage may be tied less to the source voltage (or other voltage applied via the field electrode contact) than at the field electrode contact.

The field electrode contact or contacts may electrically connect the field electrode to a wiring structure above, for instance to a metallization arranged above the first side of the semiconductor body. In between the metallization and the semiconductor body, an insulating layer may be arranged, the field electrode contact or contacts intersecting the insulating layer vertically.

In an embodiment, the semiconductor body aside the field electrode trench has lateral sections with a respective average specific resistance Rn, wherein Rn−1 is smaller than Rn. Therein, n may be any natural number ≥2. The respective specific resistance may be taken as an average over the respective section, an absolute resistance may be constant or vary over the respective section. The section n−1, in which the resistance Rn−1 is smaller than Rn (the resistance in the subsequent section n), is closer to the field electrode contact than the section n. If, for example, one considers a first specific resistance R₁ in a first lateral section of the field electrode and a second specific resistance R₂ in a second lateral section of the field electrode, wherein the first section is arranged closer to the field electrode contact than the second section, the first specific resistance R₁ is smaller than the second specific resistance R₂. Optionally, the semiconductor body may have a third specific resistance R₃ in a third lateral section of the field electrode, wherein the second lateral section is arranged closer to the field electrode contact than the third section, and wherein the second specific resistance R₂ is smaller than the third specific resistance R₃. There may be several ways for increasing the specific resistance R in the semiconductor body aside the field electrode trench along the length direction from a first position x₁ aside the field electrode contact to a second position x₂ away from the first position x₁, which will be described in detail in the following.

In an embodiment, the specific resistance R in the semiconductor body is adapted by an additional doping which is introduced into the semiconductor body. The additional doping can for instance be arranged below the channel of the device, e.g. below the body region. To decrease the resistance, for example, the additional doping may be made of a first doping type, e.g. be arranged below the body region, for instance at an upper end of the drift region.

In an embodiment, at least an average concentration cₘₑₐₙ of the additional doping is different in the n lateral sections. Therein, the average concentration is taken as a mean value over the respective section. If one considers, for example, an additional doping which lowers the specific resistance, the average concentration cₘₑₐₙ may be larger in a first lateral section arranged closer to the field electrode contact than in a subsequent second lateral section (in which the specific resistance is larger, see above). Considering again an optional third lateral section, the second lateral section being closer to the field electrode contact than the third lateral section, the average concentration of the additional doping may be smaller in the third section than in the second section, e.g. even be zero in the third section.

In an embodiment, the additional doping has different absolute concentrations c_{abs} in the n lateral sections. This may be realized with different masks, a first absolute concentration in the first lateral section and a second absolute concentration in the second lateral section being applied by different implantation steps. In this case, the absolute concentration may be constant over a respective section, e.g. the average concentration cₘₑₐₙ being equal to the absolute concentration c_{abs} in a respective section.

In an embodiment, which may be combined with the different absolute concentrations or be an alternative thereto, a doping profile of the additional doping has first maxima along a first section and second maxima along a second lateral section. Therein, the doping profile in the first and the second lateral section differs in an extension (width) of the first maxima compared to an extension of the second maxima, and/or a distance between the first maxima compared to a distance between the second maxima.

If, for example, the additional doping decreases the resistance, the extension of the first maxima may be larger compared to the extension of the second maxima and/or the distance between the first maxima may be smaller compared to the distance between the second maxima. In other words, a duty cycle of the first maxima in the first lateral section may be higher compared to a duty cycle of the second maxima in the second lateral section. Vice versa, if one considers, for example, an additional doping which increases the resistance, the extension of the first maxima may be smaller compared to the extension of the second maxima and/or the distance between the first maxima may be larger compared to the distance between the second maxima. In other words, the duty cycle of the first maxima in the first lateral section may be smaller compared to the duty cycle of the second maxima in the second lateral section.

Independently of whether the additional doping increases or decreases the resistance, the extension of a respective maximum can for instance be taken as full width at half maximum. The distance between two maxima may be taken as the clearance between these maxima, i.e. between the two flanks facing each other of the maxima, for instance from half of maximum value to half of maximum value.

In an embodiment, the first maxima and the second maxima have the same height. In other words, the additional doping may have the same absolute concentration c_{abs} in the first lateral section and in the second lateral section. The different average concentration cₘₑₐₙ may then be adjusted only via the different duty cycle of the first and second maxima, e.g. in the same doping step with a mask having respective openings in the first and second lateral section.

In an embodiment, the additional doping is arranged below the body region of the device, e.g. at an upper end of the drift region. The additional doping may be made of the same doping type like the drift region, e.g. first doping type, and have a higher doping concentration compared to the drift region. As seen for instance in a cross-sectional view, the sectional plane lying parallel to the vertical and to the transverse direction, the additional doping may lie adjacent to the side wall of the field electrode trench and/or adjacent to a lower end of the body region. Independently of these details, the additional doping may for instance reduce the specific resistance, e.g. at the first position (where the field plate potential is low during switching).

In an embodiment, the field electrode trench has an increasing width from the first to the second position, e.g. from the field electrode contact to the open end. The width of the field electrode, which is also taken in the transverse direction, may increase together with the width of the field electrode trench, a field oxide thickness being for instance basically constant along the field electrode trench. The trench width may increase continuously or stepwise, e.g. have a first width w₁ in a first lateral section and a second width w₂ in a second lateral section, where w₂ is larger than w₁. With the increasing width of the field electrode trench, the increasing resistance may be realized geometrically, for instance due to a decreasing mesa width. This may be combined with an additional doping or be an alternative thereto.

In an embodiment, the device comprises an additional field electrode trench, wherein the field electrode trenches are arranged aside each other with respect to the transverse direction. Therein, a distance d taken between the field electrode trenches in the transverse direction decreases from the first position to the second position, e.g. from the field electrode contact towards the open end. Due to the decreasing distance, the specific resistance may increase for geometrical reasons. The decreasing distance may be combined with the increasing trench width discussed above. Consequently, though having a decreasing distance from each other along the length direction, the trenches may be arranged parallel to each other (e.g. considering a respective length axes lying centrally in the respective trench).

In an embodiment, a load contact, e.g. source contact, is arranged laterally between the field electrode trenches. As discussed above for the field electrode contact, it may vertically intersect an insulating layer arranged above the semiconductor body, the load contact reaching to or into the semiconductor body. The load contact makes electrical contact to the semiconductor body, i.e. to a load region of the device, for instance to a source region. Such a source contact may be provided as a combined body/source contact, i.e. make also electrical contact to the body region as well.

In an embodiment, a contact width of the load or source contact, which is taken in the transverse direction, decreases along the length direction from the first position towards the second position, i.e. from the field electrode contact towards the open end. The contact width increasing from the second to the first position, e.g. from the open end towards the field electrode contact, may suppress parasitics, e.g. a parasitic bipolar.

In an embodiment, the increase of the width w of the field electrode trench, and/or the decrease of the distance d between the field electrode trenches, and/or the decrease of the contact width cw of the load/source contact, is stepwise from the first position to the second position, e.g. from the field electrode contact to the open end.

In an embodiment, the increase of the width w of the field electrode trench, and/or the decrease of the distance d between the field electrode trenches, and/or the decrease of the contact width cw of the source contact, is continuous in the length direction from the first position to the second position, e.g. from the field electrode contact to the open end. In other words, the width w and/or distance d and/or contact width cw may have a taper from the first to the second position.

In an embodiment, a semiconductor package comprises a semiconductor die with a semiconductor transistor device, the semiconductor die mounted for instance on a substrate or heatsink. Though in general any electrical contact formation is conceivable, like wire or ribbon bonding, an embodiment relates to a clip bonding. The clip can for instance be made of copper and/or be a stamped part. Independently of these details, the clip makes electrical contact to the transistor device, e.g. to the load region/source region arranged at the first side of the semiconductor body.

In an embodiment, as seen in a vertical top view, i.e. looking vertically onto the first side of the semiconductor die, the first position is arranged aside the clip, i.e. not below the clip. In other words, that region of the semiconductor body, in which the specific resistance is smaller, is arranged aside the clip. Alternatively, or in addition, the second position, e.g. open end, may be arranged below the clip. In other words, that region of the semiconductor body, where the specific resistance in the semiconductor body is higher, may be arranged below the clip.

In an embodiment, a method of manufacturing the semiconductor device comprises: etching the field electrode trench into the semiconductor body; forming the field electrode in the field electrode trench; forming the field electrode contact.

As to further options and details, reference is made to the description above. By way of example, the additional doping having a different absolute concentration in the n lateral sections may be made in subsequent implantation steps, e.g. a first mask defining the first lateral section in one step and a second mask defining the second lateral section in another step. Alternatively, the doping profile having first and second maxima may be formed in a common implantation step, e.g. the same mask defining the first maxima in the first lateral section and defining the second maxima in the second lateral section.

### BRIEF DESCRIPTION OF THE DRAWINGS

Below, the semiconductor transistor device and method of manufacturing are explained in further detail by means of exemplary embodiments, wherein the individual features can also be relevant in a different combination.

FIG. 1 shows a semiconductor transistor device in a vertical cross-section the sectional plane parallel to a transverse direction;

FIG. 2 shows a semiconductor transistor device in a vertical cross-section, the sectional plane parallel to a length direction;

FIG. 3 shows a semiconductor transistor device in a vertical cross-section, the sectional plane parallel to a length direction;

FIG. 4a illustrates a semiconductor transistor device with a plurality of device cells in a horizontal cross-section;

FIG. 4b illustrates a doping profile of an additional doping of the device of FIG. 4a;

FIG. 5a illustrates a semiconductor transistor device with a plurality of device cells in a horizontal cross-section;

FIG. 5b illustrates a doping profile of an additional doping of the device of FIG. 5a;

FIG. 6 illustrates a semiconductor transistor device with a plurality of device cells in a horizontal cross-section;

FIG. 7 illustrates a semiconductor transistor device with a plurality of device cells in a horizontal cross-section;

FIG. 8 illustrates a semiconductor transistor device with a plurality of device cells in a horizontal cross-section;

FIG. 9 illustrates a semiconductor transistor device with a plurality of device cells in a horizontal cross-section;

FIG. 10 shows a semiconductor transistor device in a vertical cross-section, the sectional plane lying parallel to a length direction;

FIG. 11 shows the semiconductor transistor device of FIG. 10 in a horizontal cross-section;

FIG. 12 illustrates a dependence of an on-resistance from a field electrode voltage;

FIG. 13 summarizes some process steps in a flow diagram.

### DETAILED DESCRIPTION

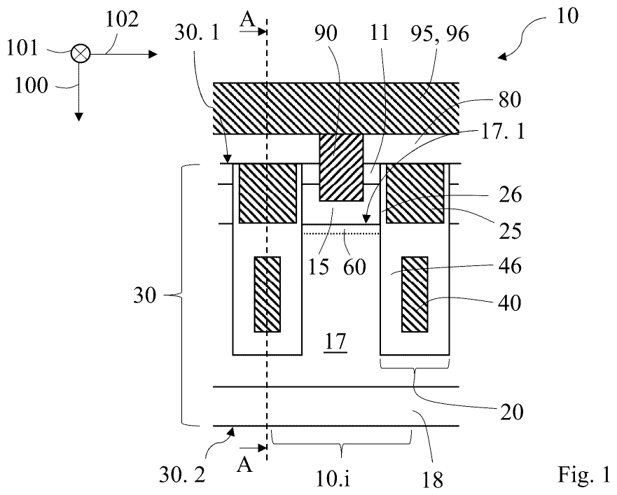

FIG. 1 illustrates a semiconductor transistor device 10 in a vertical cross-section. It comprises a source region 11 and a drain region 18, the source region 11 arranged at a first side 30.1 of a semiconductor body 30 and the drain region 18 arranged at a second side 30.2 of the semiconductor body 30. Below the source region 11, a body region 15 is arranged, a drift region 17 being disposed between the body region 15 and the drain region 18. In the example shown, the source region 11, drift region 17 and drain region 18 are n-type and the body region is p-type.

A field electrode trench 20 extends from the first side 30.1 into the semiconductor body 30. It comprises a field electrode 40 in a lower portion and a gate electrode 25 in an upper portion. Via a field dielectric 46, the field electrode 40 capacitively couples to the drift region 17. The gate electrode 25 capacitively couples to the body region 15 via a gate dielectric 26.

On the first side 30.1 of the semiconductor body 30, an insulating layer 80 is arranged. A source contact 90 intersects the insulating layer 80 vertically, i.e. in a vertical direction 100, and connects the source region 11 and body region 15 to a metallization 95 above, in the example shown to a source plate 96. The sectional plane of FIG. 1 lies parallel to a transverse direction 102, in which a plurality of device cells 10.i are arranged consecutive. In a length direction 101 perpendicular thereto, the field electrode trench 20, as well as the gate electrode 25 and field electrode 40, have an elongated lateral extension.

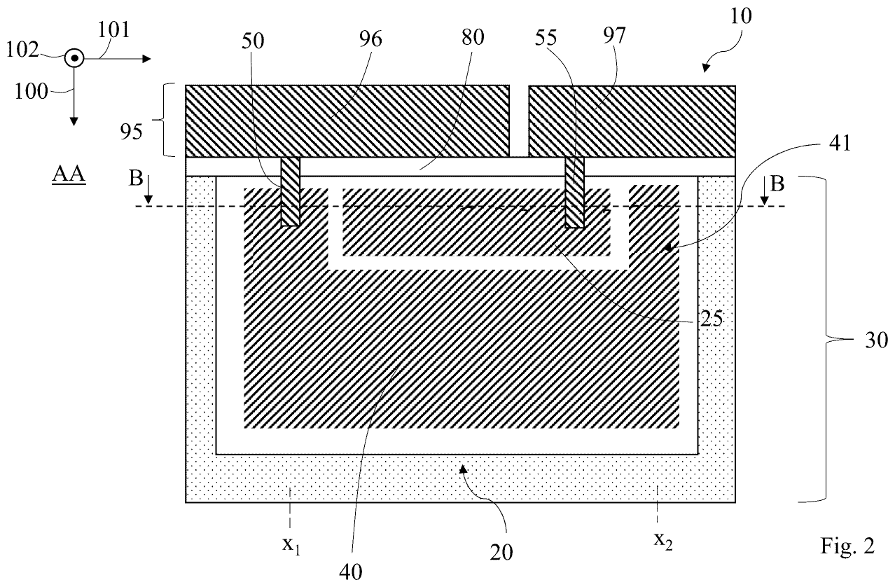

This is illustrated in FIG. 2, which shows a cross-section parallel to the length direction 101. The sectional plane AA runs through the field electrode trench 20, see AA as referenced in FIG. 1. Generally, in this disclosure, the like reference numerals indicate the like elements or elements having the like function, and reference is made to the description of the respectively other figures as well.

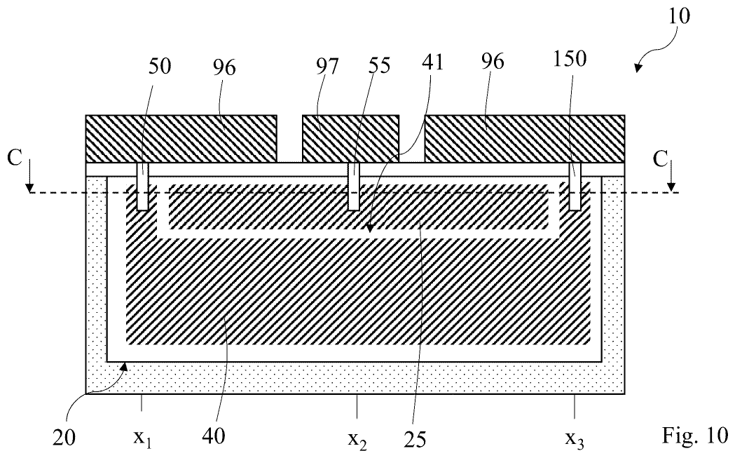

Via a field electrode contact 50, which intersects the insulating layer 80 vertically, the field electrode 40 is electrically connected to the metallization 95, in the example shown to the source plate 96. The field electrode contact 50 is arranged at a first position, and the field electrode 40 is not connected at a second position x₂, i.e. at an open end 41. In the example of FIG. 2, the first and second position x₁, x₂ are arranged at opposite lateral ends of the field electrode trench 20, an alternative arrangement as shown in FIG. 10/11.

Aside the source plate 96, a gate pad 97 is formed in the metallization 95. It is electrically connected to the gate electrode 25 via a gate contact 55 which intersects the insulating layer 80 vertically, like the field electrode contact 50 and the source contact 90. In the example shown, the contacts are shown as separate elements, e.g. made of tungsten. Alternatively, they can be formed of the same layer or layer stack like the metallization 95, the metallization 95 making an electrical contact to the semiconductor body 30 where the insulating layer 80 is opened.

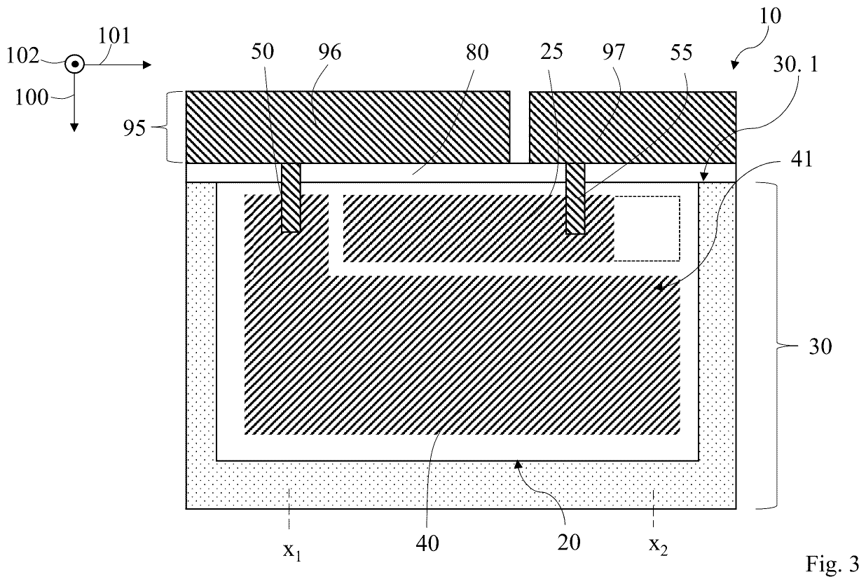

FIG. 3 shows a sectional view comparable to FIG. 2, the embodiment differs only in the vertical extension of the field electrode 40. At the open and 41, the field electrode 40 does not extend up to the first side 30.1 of the semiconductor body 30; it reaches only up where the field electrode contact 50 is arranged. Above the open end 41, the field electrode trench 20 can be filled with oxide or the gate electrode 25 may extend further and cover the field electrode 40 upwards, as indicated schematically by dashed lines.

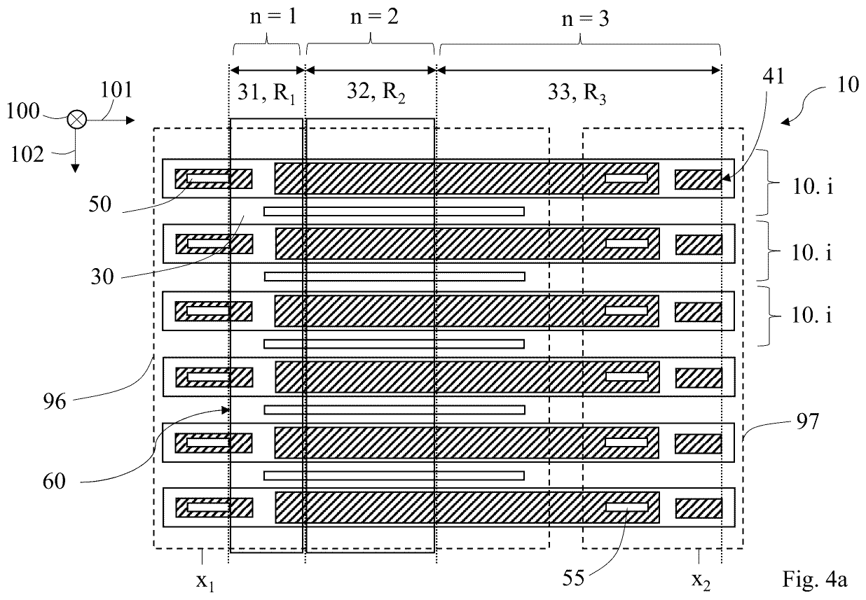

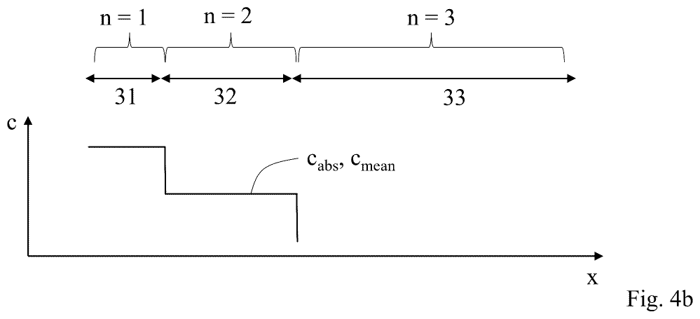

FIG. 4a shows a semiconductor transistor device 10 comprising a plurality of device cells 10.i in a horizontal cross-section. The sectional plane lies parallel to the length direction 101 and to the transverse direction 102 and goes through the gate electrode 25, see the sectional plane BB as indicated in FIG. 2. A specific resistance R in the semiconductor body 30 increases from the first position x₁, i.e. field electrode contact 50, to the second position x₂, i.e. open end 41. For orientation and comparison with FIG. 2, the source pad 96 and the gate pad 97 are indicated as hatched lines.

In the example shown in FIG. 4a, the semiconductor body 30, which is arranged aside the field electrode trench 20 with respect to the transverse direction 102, has in n lateral sections a respective average specific resistance Rn, wherein n=3 in case of FIG. 4a. In detail, the semiconductor body 30 has a first average specific resistance R₁ in a first lateral section 31, a second specific resistance R₂ in a second lateral section 32 and a third average specific resistance R₃ in a third lateral section 33. Therein, R₁ one is smaller than R₂ and R₂ is smaller than R₃.

FIG. 4b illustrates a doping concentration c of an additional doping 60 introduced in the first and second lateral section 31, 32 to reduce the resistance. The position of the additional doping 60 is indicated by a dotted line in FIG. 1, it is arranged at an upper end 17.1 of the drift region 17. The additional doping 60 is made of the same doping type like the drift region 17, which is n-type in the example shown, and reduces the specific resistance R in the semiconductor body 30.

As illustrated in FIG. 4b, a respective average concentration cₘₑₐₙ of the additional doping is different for different lateral sections 31-33. In detail, it is higher in the first lateral section 31 than in the second lateral section 32 and it is zero in the third lateral section 33. In case of FIG. 4b, this is adapted via a respective absolute concentration c_{abs}, which is higher in the first lateral section 31 and zero in the third lateral section 33. This can be achieved in subsequent doping steps with different masks, e.g. a first mask having an opening in the first and the second lateral section 31, 32 and a second mask with an opening in the first lateral section 31 only, or, alternatively, a first mask having an opening in the first lateral section 31 only and a second mask having an opening in the second lateral section 32 only.

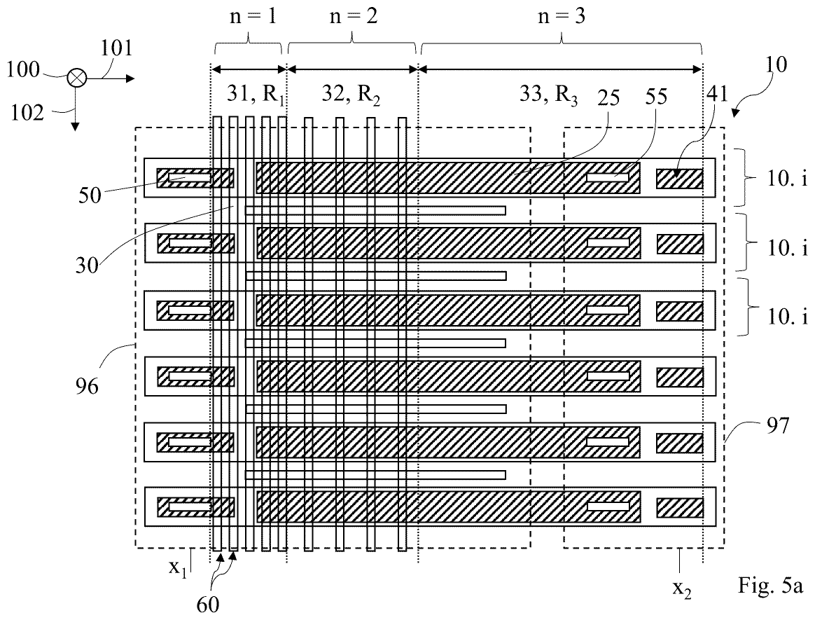

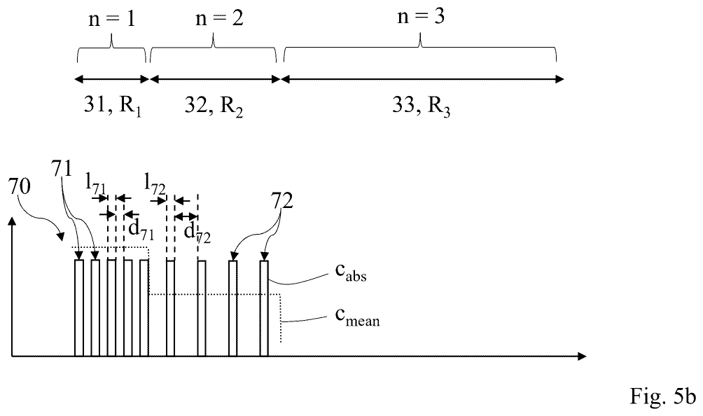

FIGS. 5a and 5b illustrate a semiconductor transistor device 10, which is largely comparable to the embodiment of FIGS. 4a and 4b. It also has a respective average specific resistance Rn in a respective lateral section 31-33, wherein the increasing resistance is adjusted via a decreasing average concentration cₘₑₐₙ of the additional doping, see FIG. 5b.

In a case of FIGS. 5a and 5b, an absolute concentration c_{abs} of the additional doping is equal in the first and second lateral section 31, 32, the additional doping may be introduced with a common mask in the same step. To adjust the differing average concentration cₘₑₐₙ, a doping profile 70 has first maxima 71 in the first lateral section 31 and second maxima 72 in the second lateral section 32, wherein a distance d₇₁ between the first maxima is smaller than a distance d₇₂ between the second maxima 72. Alternatively or in addition, different average concentrations cₘₑₐₙ could also be adjusted by providing the first maxima with a larger extension e₇₁ compared to the extension e₇₂ of the second maxima 72.

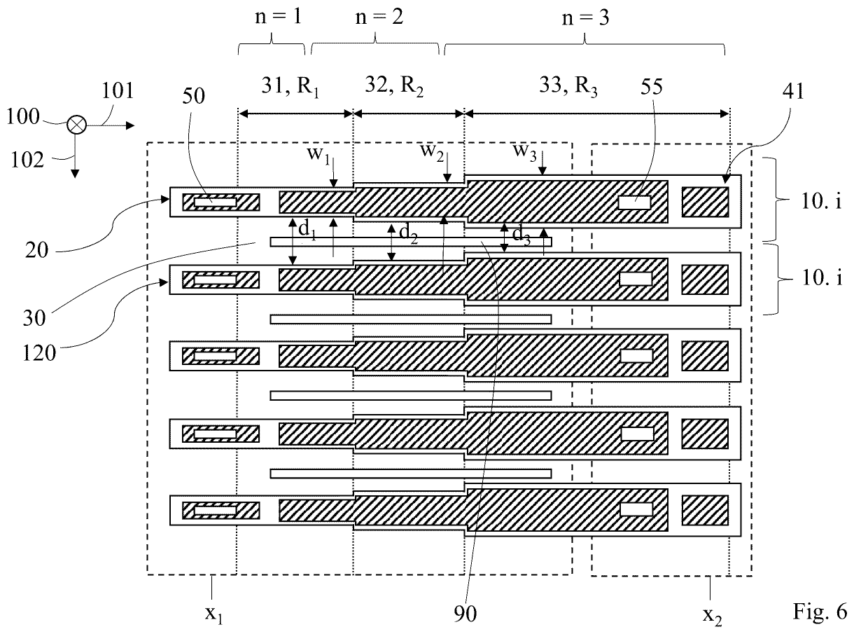

FIG. 6 shows a semiconductor transistor device 10 in a horizontal cross-section and illustrates a further possibility for adjusting a specific resistance R in the semiconductor body 30, which increases from the first position x₁ to the second position x₂, i.e. from the field electrode contact 50 to the open end 41. The field electrode trench 20 has a first width w₁ in the first lateral section 31, a second width w₂ in the second lateral section 32, and a third width w₃ in the third lateral section 33, where w₁<w₂<w₃.

Considering an additional field electrode trench 120 of a neighboring device cell 10.i, a distance d between the field electrode trenches 20, 120 decreases from the first lateral position x₁ to the second lateral position x₂. A third distance d₃ in the third lateral section 33 is smaller than a second distance d₂ in the second lateral section 32, which in turn is smaller than the first distance d₁ in the first lateral section 31. Vice versa, the resistance in the semiconductor body 30 increases from the first over the second to the third lateral section 31-33.

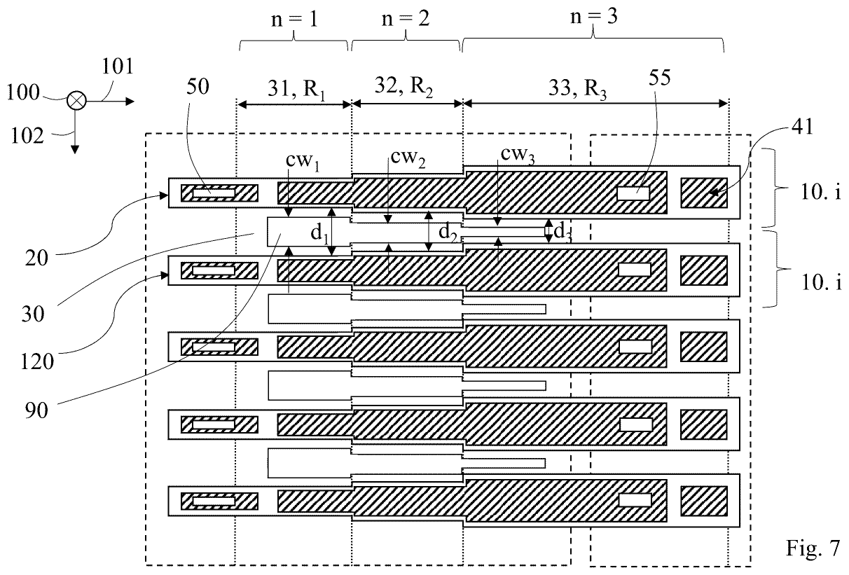

In the embodiment of FIG. 6, the source contact 90 arranged on a lateral position between the field electrode trenches 20, 120 has, taken in the transverse direction 102, a constant width along the length direction 101. The embodiment of FIG. 7 basically corresponds to the one shown in FIG. 6, i.e. also shows a stepwise decreasing distance d₁−d₃ along the length direction 101. In contrast to the embodiment of FIG. 6, the source contact 90 has a decreasing width cw in the length direction. In the example of FIG. 7, it decreases stepwise like the distance d.

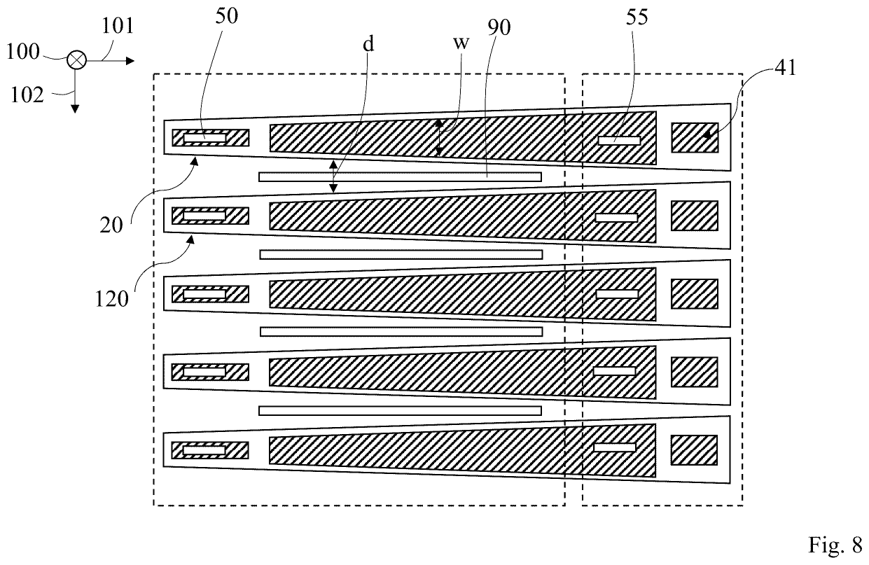

FIG. 8 shows a horizontal cross-section of a semiconductor transistor device 10, wherein a distance d between the field electrode trenches 20, 120 decreases along the length direction 101. In contrast to FIGS. 6 and 7, the increase of the width w of the field electrode trench 20 and, vice versa, decrease of the distance d is continuous along the length direction 101, i.e. not stepwise.

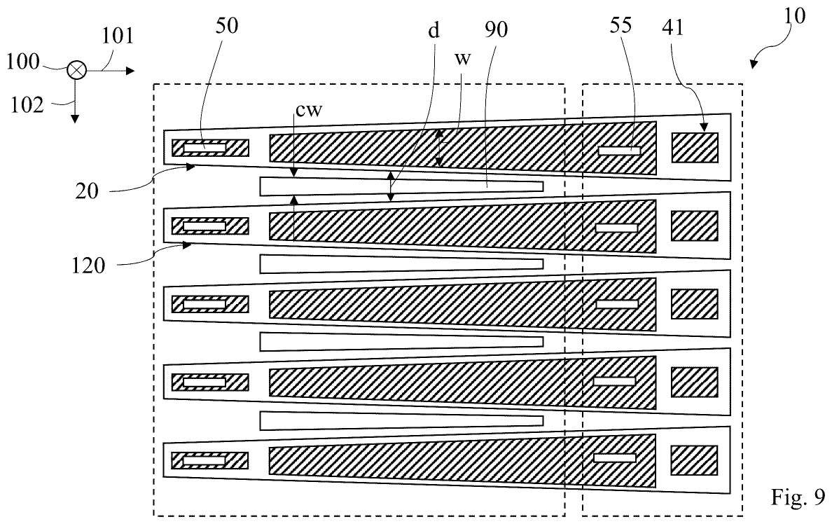

FIG. 9 also shows field electrode trenches 20, 120 with a continuously increasing width w and, vice versa, decreasing distance d. In contrast to the embodiment of FIG. 8, the source contact 90 has a decreasing contact width cw, wherein the contact width cw decreases continuously along the length direction 101.

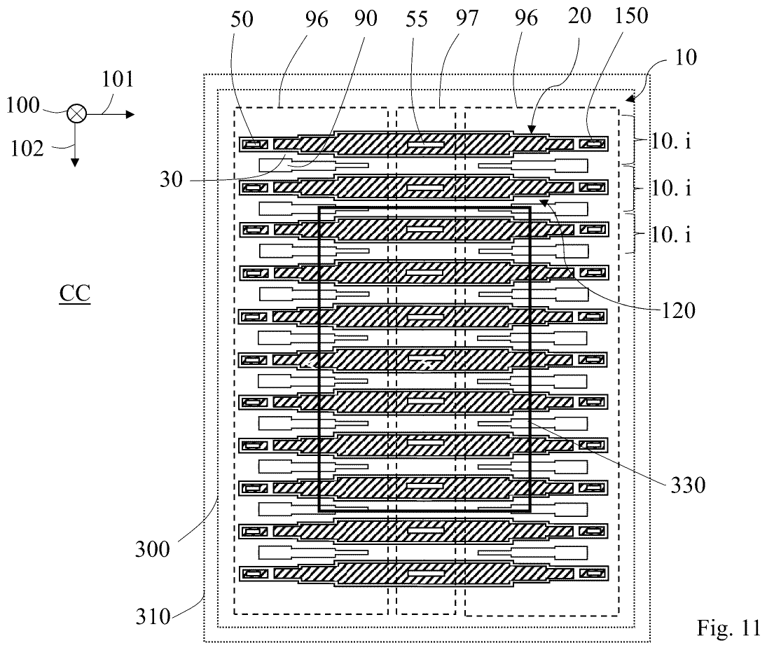

FIGS. 10 and 11 illustrate a semiconductor transistor device 10 in a vertical cross-section (FIG. 10) and in a horizontal cross-section (FIG. 11). In contrast to the embodiments discussed above, the open end 41 is not arranged at a lateral end of the field electrode 40. Since the gate electrode 25 is connected centrally, the field electrode 40 has its open end 41 centrally as well. The field electrode contact 50 is arranged at one lateral end of the field electrode 40, an additional field electrode contact 150 is arranged at a laterally opposite end. In between, at the open end 41, the field electrode 40 is not tied to the source voltage, e.g. source plate 96. In the semiconductor body aside the field electrode trench 20, the specific resistance R increases from the first position x₁ to the second position x₂, and it also increases from a third position x₃ at the additional field electrode contact 150 to the second position x₂.

FIG. 11 illustrates this arrangement in a horizontal cross-section, see the sectional plane CC as indicated in FIG. 10. The source pads 96 and the gate pad 97 are indicated as hatched lines. The field electrode (not shown here) is contacted by the field electrode contacts 50, 150 at both lateral ends, the gate pad 97 and gate contact 55 are arranged centrally.

In the example shown, the specific resistance R increasing from the field electrode contacts 50, 150 to two the center, respectively, is adjusted via a decreasing distance d (not referenced here, see FIGS. 6 and 7 for comparison) between the field electrode trenches 20, 120. Alternatively or in addition, the specific resistance R increasing towards the center could also be adjusted by an additional doping, see above.

A semiconductor die 300, in which the device 10 is formed, is shown schematically by a dotted line. Further, a package 310, in which the semiconductor die 300 is mounted, is shown schematically by another dotted line. The device 10, i.e. source region, is contacted in the package 310 via a bond clip 330. The metallization of the device may comprise a top metal layer above the metal pads shown schematically in FIG. 11, wherein for instance one common source pad is formed in this metallization layer (the gate wiring shown is realized in a metallization layer below).

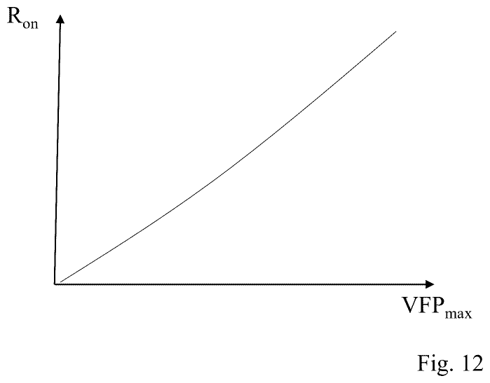

FIG. 12 illustrates a dependence of the on-resistance Rₒₙ from the field electrode voltage VFP. As discussed in the general description, the on-resistance increases with an increasing field electrode voltage.

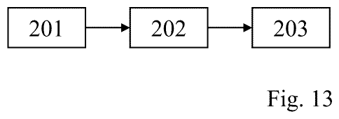

FIG. 13 summarizes some manufacturing steps in a flow diagram. A method of manufacturing the semiconductor transistor device may comprise etching 201 the field electrode trench, forming 202 the field electrode, and forming 203 the field electrode contact.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor transistor device, comprising:
a field electrode trench in a semiconductor body;
a field electrode in the field electrode trench;
a field electrode contact electrically contacting the field electrode,
wherein the field electrode trench and the field electrode have an elongated lateral extension in a length direction,
wherein a specific resistance in the semiconductor body aside the field electrode trench increases along the length direction from a first position aside the field electrode contact to a second position away from the first position.

2. The semiconductor transistor device of claim 1, wherein the semiconductor body aside the field electrode trench has, in n lateral sections along the field electrode in the length direction, a respective average specific resistance Rₙ, and wherein Rₙ₋₁<Rₙ.

3. The semiconductor transistor device of claim 1, further comprising:
an additional doping in the semiconductor body,
wherein the additional doping adapts the specific resistance in the semiconductor body.

4. The semiconductor transistor device of claim 3, wherein the semiconductor body aside the field electrode trench has, in n lateral sections along the field electrode in the length direction, a respective average specific resistance Rₙ, and wherein Rₙ₋₁<Rₙ, and wherein at least a respective average concentration of the additional doping is different in the n lateral sections.

5. The semiconductor transistor device of claim 4, wherein the additional doping has different absolute concentrations in the n lateral sections.

6. The semiconductor transistor device of claim 4, wherein a dopant profile of the additional doping has first maxima along a first one of the n lateral sections and has a second maxima along a second one of the n lateral sections, wherein the dopant profile in the first section and the second section differ in at least one of:
an extension of the first maxima compared to an extension of the second maxima, and
a distance between the first maxima compared to a distance between the second maxima.

7. The semiconductor transistor device of claim 6, wherein the first maxima and the second maxima of the dopant profile have a same height.

8. The semiconductor transistor device of claim 3, further comprising:
a body region; and
a drift region below the body region,
wherein the additional doping is arranged below the body region at an upper end of the drift region.

9. The semiconductor transistor device of claim 1, wherein a width of the field electrode trench and of the field electrode, taken in a transverse direction lying perpendicular to the length direction, increases from the first position to the second position.

10. The semiconductor transistor device of claim 1, further comprising:
an additional field electrode trench in the semiconductor body,
wherein the additional field electrode trench is arranged aside the field electrode trench in a transverse direction which lies perpendicular to the length direction,
wherein a distance taken between the field electrode trench and the additional field electrode trench in the transverse direction decreases in the length direction from the first position to the second position.

11. The semiconductor transistor device of claim 10, further comprising:
an insulating layer arranged on the semiconductor body; and
a source contact vertically intersecting the insulating layer,
wherein the source contact is arranged laterally between the field electrode trench and the additional field electrode trench,
wherein a contact width of the source contact, taken in the transverse direction, decreases in the length direction from the first position to the second position.

12. The semiconductor transistor device of claim 11, wherein a decrease of the contact width of the source contact is stepwise in the length direction from the first position to the second position.

13. The semiconductor transistor device of claim 11, wherein a decrease of the contact width of the source contact is continuous in the length direction from the first position to the second position.

14. The semiconductor transistor device of claim 10, wherein a decrease of the distance between the field electrode trench and the additional field electrode trench is stepwise in the length direction from the first position to the second position.

15. The semiconductor transistor device of claim 10, wherein a decrease of the distance between the field electrode trench and the additional field electrode trench is continuous in the length direction from the first position to the second position.

16. The semiconductor transistor device of claim 9, wherein an increase of the width of the field electrode trench is stepwise in the length direction from the first position to the second position.

17. The semiconductor transistor device of claim 9, wherein an increase of the width of the field electrode trench is continuous in the length direction from the first position to the second position.

18. A semiconductor package, comprising:
a semiconductor die with the semiconductor transistor device of claim 1; and
a clip in electrical contact to a source region of the semiconductor transistor device,
wherein, as seen in a vertical top view onto the semiconductor die, the first position is arranged aside the clip.

19. A semiconductor package, comprising:
a semiconductor die with the semiconductor transistor device of claim 1; and
a clip in electrical contact to a source region of the semiconductor transistor device,
wherein, as seen in a vertical top view onto the semiconductor die, the second position is arranged below the clip.

20. A method of manufacturing a semiconductor transistor device, the method comprising:
etching a field electrode trench into a semiconductor body;
forming a field electrode in the field electrode trench;
forming a field electrode contact electrically contacting the field electrode,
wherein the field electrode trench and the field electrode have an elongated lateral extension in a length direction,
wherein a specific resistance in the semiconductor body aside the field electrode trench increases along the length direction from a first position aside the field electrode contact to a second position away from the first position.
